(19) United States
(12) Patent Application Publication
(10) Pub. No.: US 2020/0407282 A1
(43) Pub. Date: Dec. 31, 2020

(54) CERAMIC MATERIAL BASED ON ZIRCONIUM OXIDE WITH FURTHER OXIDES

(71) Applicant: Siemens Aktiengesellschaft, Munich (DE)

(72) Inventors: Arturo Flores Renteria, Berlin (DE); Werner Stamm, Mülheim an der Ruhr (DE)

(73) Assignee: Siemens Aktiengesellschaft, Munich (DE)

(21) Appl. No.: 16/979,099

(22) PCT Filed: Feb. 26, 2019
(86) PCT No.: PCT/EP2019/054650

§ 371 Date: Sep. 8, 2020

(30) Foreign Application Priority Data
Mar. 23, 2018 (DE) 10 2018 204 498.8

(51) Int. Cl. C04B 37/02; C04B 35/48; C23C 4/11; C23C 14/30; C23C 28/00; C23C 14/16; C23C 14/08; C23C 4/134

(52) U.S. Cl. CPC C04B 37/023; F01D 5/284; C23C 4/11; C23C 14/30; C23C 28/3215; C23C 28/3455; C23C 14/16; C23C 14/083; C23C 4/134; C04B 2235/3244; C04B 2235/3224; C04B 2235/3229; C04B 2235/3208; C04B 2235/3206; C04B 2237/405; C04B 2237/348; C04B 2237/123; C04B 2237/704; C04B 35/48

(57) ABSTRACT

A ceramic material is provided by deliberately choosing the additions of oxides to form zirconium oxide, in particular for the use of a layer system which has a high resistance to sintering, high expansion tolerance and low thermal conductivity.

### CROSS REFERENCE TO RELATED APPLICATIONS

This application is the U.S. National Stage of International Application No. PCT/EP2019/054650 filed 26 Feb. 2019, and claims the benefit thereof. The International Application claims the benefit of German Application No. DE 10 2018 204 498.8 filed 23 Mar. 2018. All of the applications are incorporated by reference herein in their entirety.

### FIELD OF INVENTION

The invention relates to a ceramic material which can, in particular, be employed in the use of ceramic layers.

### BACKGROUND OF INVENTION

The use of zirconium oxide-based ceramic materials is known from the use for ceramic heat shields made from solid material or ceramic protective layers on turbine blades or high-temperature components. It is important here that a high sintering resistance, phase stability, a high fracture toughness and high expansion tolerance is present.

### SUMMARY OF INVENTION

It is therefore an object of the invention to improve existing material systems.

The object is achieved by a ceramic material as claimed.

Further advantages are listed in the further dependent claims, and these can be combined with one another in any way in order to achieve further advantages.

### BRIEF DESCRIPTION OF THE DRAWINGS

FIGS. 1, 2 schematically show layer systems composed of a ceramic material.

### DETAILED DESCRIPTION OF INVENTION

It is proposed that from 4 mol % to 30 mol % of cerium oxide (CeO₂), calcium oxide (CaO) and/or magnesium oxide (MgO) be used as further optional oxides and from 2 mol % to 30 mol % of erbium oxide (Er₂O₃) and/or ytterbium oxide (Yb₂O₃) be used as base oxide.

Such a ceramic layer has, in particular, a layer thickness of from 20 μm to 1000 μm, in particular up to 2000 μm, and can advantageously be produced by means of thermal spraying, in particular APS or EB-PVD.

The ceramic material has a high sintering resistance, a high expansion tolerance and high fracture toughness and also has a relatively low thermal conductivity.

Working examples:

ZrO₂+
Er₂O₃+Yb₂O₃
Yb₂O₃
Er₂O₃ (3 variants with base oxides)

The following can in each case be added as further oxides
CeO₂
CaO
MgO
CeO₂+CaO
CeO₂+MgO
CaO+MgO
CeO₂+CaO+MgO
to the above 3 variants, i.e. a total of 21 variants.

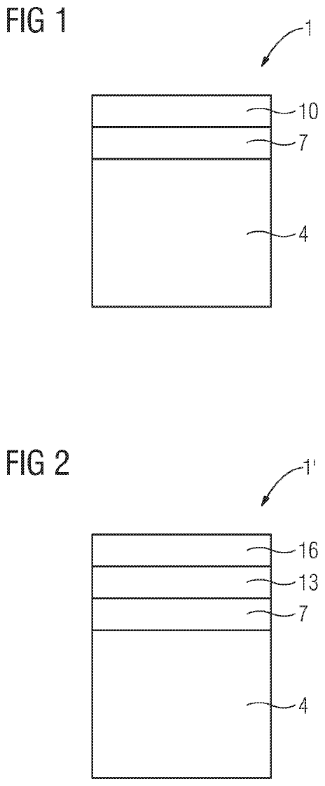

FIG. 1 shows a layer system 1 according to the invention.

The layer system 1 has a substrate 4. The substrate 4 is, in particular, a nickel-based superalloy or is a CMC substrate.

A bonding layer which, particularly in the case of a nickel-based superalloy, is an NiCoCrAlY-based alloy or an aluminide layer or a platinum-aluminide layer is present on the substrate 4.

During coating or during operation, an oxide layer (TGO) is formed on this metallic bonding agent layer.

A ceramic layer as per the ceramic material has been applied on top of this oxide layer (TGO) or on the metallic bonding agent layer 7.

In the case of a ceramic substrate 4 (CMC), a bonding layer for the ceramic layer 10 may not be necessary.

FIG. 2 shows a variant in which the layer system 1′ has a two-ply ceramic protective layer. As regards the substrate and/or the substrate materials of the bonding layer 7, what has been said in the case of FIG. 1 applies analogously. However, the outermost ceramic layer 16 here forms the ceramic material of the invention.

A ceramic bonding layer 13 is present under this ceramic layer 16 for the purpose of matching coefficients of thermal expansion or matching the porosities.

1. A ceramic material comprising:
zirconium oxide (ZrO₂) together with ytterbium oxide (Yb₂O₃) and/or erbium oxide (Er₂O₃) as base oxide or base oxides, and
optionally at least one further oxide selected from the group consisting of: cerium oxide (CeO₂), calcium oxide (CaO) and magnesium oxide (MgO).

2. The ceramic material as claimed in claim 1,
wherein only erbium oxide (Er₂O₃) and ytterbium oxide (Yb₂O₃) are used as base oxides.

3. The ceramic material as claimed in claim 1,
wherein only erbium oxide (Er₂O₃) is used as base oxide.

4. The ceramic material as claimed in claim 1,
wherein only ytterbium oxide (Yb₂O₃) is used as base oxide.

5. The ceramic material as claimed in claim 1, comprising:
a base oxide or base oxides, and
at least one further oxide.

6. The ceramic material as claimed in claim 1,
wherein only calcium oxide (CaO) and cerium oxide (CeO₂) are used as further oxides.

7. The ceramic material as claimed in claim 1,
wherein only calcium oxide (CaO) and magnesium oxide (MgO) are used as further oxides.

8. The ceramic material as claimed in claim 1,
wherein only magnesium oxide (MgO₂) and cerium oxide (CeO₂) are used as further oxides.

9. The ceramic material as claimed in claim 1,
wherein only cerium oxide (CeO₂) is used as further oxide.

10. The ceramic material as claimed in claim 1,
wherein only magnesium oxide (MgO) is used as further oxide.

11. The ceramic material as claimed in claim 1,
wherein only magnesium oxide (MgO), calcium oxide (CaO) and cerium oxide (CeO₂) are used as further oxides.

12. The ceramic material as claimed in claim 1, comprising:
2 mol %-30 mol % of ytterbium oxide (Yb₂O₃) and/or erbium oxide (Er₂O₃).

13. The ceramic material as claimed in claim 1, comprising:
4 mol %-30 mol % of cerium oxide (CeO₂), calcium oxide (CaO) and/or magnesium oxide (MgO).

14. A layer system, comprising:
a substrate based on a nickel- or cobalt-based superalloy,
a bonding layer, and
a ceramic layer based on a ceramic material as claimed in claim 1.

15. The layer system as claimed in claim 14,
wherein the ceramic layer has a layer thickness of from 20 μm to 1000 μm.

16. The layer system as claimed in claim 14,
wherein the substrate is a metallic substrate.

17. The layer system as claimed in claim 14,
wherein the bonding layer is based on NiCoCrAlY.

18. The layer system as claimed in claim 14,
wherein the ceramic layer has a layer thickness of from 20 μm up to 2000 μm.

19. The layer system as claimed in claim 15,
wherein the layer system is produced by thermal spraying, APS, or EB-PVD.

20. A ceramic material consisting of:
zirconium oxide (ZrO2) together with ytterbium oxide (Yb2O3) and/or erbium oxide (Er2O3) as base oxide or base oxides, and
optionally at least one further oxide selected from the group consisting of: cerium oxide (CeO2), calcium oxide (CaO) and magnesium oxide (MgO).
